(19) United States
(12) Patent Application Publication
(10) Pub. No.: US 2026/0282220 A1
(43) Pub. Date: Sep. 17, 2026

(54) Inlay, Component Carrier, and Method of Manufacturing the Inlay

(71) Applicant: AT&S Austria Technologie & Systemtechnik Aktiengesellschaft, Leoben (AT)

(72) Inventor: Hans PARK, Chongqing (CN)

(21) Appl. No.: 19/470,801

(22) PCT Filed: Nov. 22, 2023
(86) PCT No.: PCT/EP2023/082666

§ 371 Date: Sep. 29, 2025

(30) Foreign Application Priority Data
Mar. 30, 2023 (CN) 202310331517.8

(51) Int. Cl. H05K 1/03; H05K 1/11; H05K 1/185; H05K 3/40; H05K 3/46

(52) U.S. Cl. CPC H05K 1/036; H05K 1/115; H05K 1/185; H05K 3/4038; H05K 3/4626; H05K 2201/0215; H05K 2201/0257; H05K 2201/026

(57) ABSTRACT

An inlay includes a first electrically insulating material layer having at least one first via; a second electrically insulating material layer having at least one second via; and a central layer arranged between the first electrically insulating material layer and the second electrically insulating material layer, wherein the first via and/or the second via extend at least partially into the central layer.

### CROSS-REFERENCE TO RELATED APPLICATION

This application is a national stage application, filed under 35 U.S.C. § 371, of International Patent Application No. PCT/EP2023/082666, filed on Nov. 22, 2023, claiming priority of the filing date of the Patent Application No. 202310331517.8, filed on Mar. 30, 2023, with the China National Intellectual Property Administration, the disclosures of which are hereby incorporated by reference herein in their entirety.

### TECHNICAL FIELD

The disclosure relates to an inlay with a first electrically insulating material layer comprising a first via and a second insulating material layer comprising a second via as well as to a component carrier comprising such inlay. Further, the disclosure relates to a method of manufacturing the inlay.

Accordingly, the disclosure may relate to the technical field of component carriers, such as printed circuit boards or IC substrates, and their manufacture.

### TECHNICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, efficient protection against electromagnetic interference (EMI) becomes an increasing issue. At the same time, component carriers shall be mechanically robust and electrically and magnetically reliable to be operable even under harsh conditions.

In particular, a central problem present in the miniaturization of the component carriers and the increasing of the number layers forming the stack of the component carriers may be seen in the engineering and provision of (inlay) structures being i) on the one side stiff and mechanically stable and ii) on the other side less prone to warpage.

Known inlays in the state of the art comprise stacks of multiple glass layers with through glass vias and with a bonding film arranged between two consecutive glass layers, such as resin or conductive films.

However, conventional approaches may suffer several drawbacks. For example, the bonding film may require a conductive bridge from one glass layer to the next, which is normally achieved by means of conductive paste placed in the vias. Nevertheless, this design may suffer from cross-talking or short-circuiting between different vias. Additionally, such conventional layer build-ups may suffer from warpage issues.

### SUMMARY

There may be a need to form a layer interconnection in an efficient and robust manner.

An inlay, a component carrier and a manufacturing method are described.

According to an aspect of the disclosure, there is described an inlay comprising: a first electrically insulating material layer comprising at least one first via; a second electrically insulating material layer comprising at least one second via; and a central layer arranged between the first electrically insulating material layer and the second electrically insulating material layer, wherein the first via and/or the second via extend at least partially into the central layer.

According to a further aspect of the disclosure, there is described a component carrier comprising at least one electrically insulating layer structure and/or at least one electrically conducting layer structure, and at least one inlay according to the first aspect of the disclosure.

According to a further aspect of the disclosure, there is described a method of manufacturing an inlay, the method comprising: providing a first electrically insulating material layer comprising at least one first via; providing a second electrically insulating material layer comprising at least one second via; providing a central layer and arranging the central layer between the first electrically insulating material layer and the second electrically insulating material layer, wherein the first via and/or the second via extends at least partially into the central layer.

### OVERVIEW OF EMBODIMENTS

In the context of the present document, the term “electrically conductive layer structure” may in particular refer to a trace that comprises a metal, in particular copper. In particular, a metal trace may be configured as an elongated (preferably in the horizontal direction) electrically conductive structure that may serve for the transmission of signals, in particular high-frequency signals and/or high-speed signals. Additionally or alternatively, the metal trace may conduct electric current, in particular current in the range of 1 pA-1000 A. Further, a metal trace with a rough surface may establish an adhesion with dielectric material, thereby enhancing the stability of a component carrier. A metal trace having at least one smooth surface may provide faster signal transmission. A metal trace may have for example a shape of an elongated trace, an annular ring or may be configured as a pad or block. Sidewalls of the metal traces can be straight or inclined/curved. The electrically conductive layer structure may also denote a pad to which a via may be connected with. The electrically conductive layer may comprise a via for the interconnection of two different layers. Furthermore, a bump comprising conducting material may be provided for the interconnection between a component carrier and separated components.

In the context of the present document, the term “component carrier” may particularly denote any support structure which can accommodate one or more components thereon and/or therein for providing mechanical support and/or electrical connectivity and/or thermal conductivity. In other words, a component carrier may be configured as a mechanical and/or electronic and/or thermal carrier for components. In particular, a component carrier may be one of a printed circuit board, an organic interposer, a metal core substrate, an inorganic substrate and an IC (integrated circuit) substrate. A component carrier may also be a hybrid board combining different ones of the above-mentioned types of component carriers.

In the present context, the term “component carrier” may refer to a final component carrier product as well as to a component carrier preform (i.e. a component carrier in production, in other words a semi-finished product). In an example, a component carrier preform may be a panel that comprises a plurality of semi-finished component carriers that are manufactured together. At a final stage, the panel may be separated into the plurality of final component carrier products.

In the context of the present document, the term “via” may in particular refer to a structure that interconnects electric elements placed at opposite surfaces of a layer structure such as the first electrically insulating material layer or the second electrically insulating material layer. The via may also electrically connect the different layers to form an electrical and/or thermal conductive path of different layers. Hereby, the via may be completely or partially filled with electrically conductive material (e.g. copper). In the latter case, only the sidewalls of the via may be electrically conductive, for example a plated through-hole.

The first via and the second via each have a connecting surface, wherein the connecting surface of the first via and the connecting surface of the second via are facing each other in a z-direction (vertical direction), that is a stacking direction, of the inlay directly across the central layer. The connecting surface of the first via and of the second via might have different form, shape and/or dimension with respect to each other and might be placed at a predetermined distance from each other in the central layer. For example, the connecting surface of the first via and of the second via might be distanced 1 to 10 μm, preferably less than 5 μm from each other. It might however also be the case, that the connecting surfaces are contacting each other either in the central layer, if both the first via and the second via extend at least partially in the central layer, or inside of the first electrically insulating material layer or the second electrically insulating material layer, if the second via or the first via are penetrating through the whole central layer and up to an internal surface of or inside of the first electrically insulating material layer or the second electrically insulating material layer.

In the context of the present document, the term “central layer” may in particular refer to a layer comprising electrically insulating material and having properties being different from those of the first electrically insulating material layer and/or the second electrically insulating material layer. A central layer may also comprise the electrically conductive material.

In the context of the present document, the first electrically insulating material layer, the second electrically insulating material layer and the central layer form a stack, which might then be integrated into a component carrier.

According to an embodiment, the disclosure may be based on the idea that an (in particular electrical) interconnection between electrically insulating layers (in particular glass layers) may be provided in an efficient and robust manner, when an inlay for a component carrier structure is formed with a central (intermediate) layer between a first electrically insulating material layer and a second electrically insulating material layer, so that a first via of the first layer and a second via of the second layer extend into the central layer, respectively. This architecture may allow for effectively reducing warpage in the finished product, even by an increased thickness of the inlay due to the specific material properties of the central layer itself.

According to the present disclosure, it may be furthermore possible to have different geometries for the first via in the first electrically insulating material layer and the second insulating material layer, thus allowing a greater functional application spectrum of the inlay itself (larger design flexibility). In particular, the central layer may act as a via-to-via interconnection structure.

Another central advantage of the present disclosure may be seen in the possibility to provide one or more cavities in either or both of the first electrically insulating material layer and the second electrically insulating material layer without affecting the mechanical stability of the inlay in a disruptive manner. This is because the central layer may provide an increased mechanical stability for the whole structure.

According to an embodiment, the first electrically insulating material layer and/or the second electrically insulating material layer is made of or comprises at least one of the following materials: inorganic material/compound, (in particular glass), polymeric material or epoxy.

An inorganic compound may be a chemical compound that lacks carbon-hydrogen bonds or a chemical compound that is not an organic compound. In an example, the first electrically insulating material layer and/or the second electrically insulating material layer may comprise ceramic material, for example aluminum nitride and/or aluminum oxide and/or silicon nitride and/or boron nitride and/or tungsten comprising ceramic material. Yet, in another example, the first electrically insulating material layer and/or the second electrically insulating material layer may comprise semi-conducting material, for example silicon and/or germanium and/or silicon oxide and/or germanium oxide and/or silicon carbide and/or gallium nitride. In a further embodiment, the first electrically insulating material layer and/or the second electrically insulating material layer may comprise (elemental) metal and/or metal alloys, for example, copper and/or tin and/or bronze. Yet in another embodiment, the first electrically insulating material layer and/or the second electrically insulating material layer may comprise inorganic material, which is not listed in the above-mentioned example, such as: MoS₂, CuGaO₂, AgAlO₂, LiGaTe₂, AgInSe₂, CuFeS₂, BeO.

If the first electrically insulating material layer and/or the second electrically insulating material layer are made of or comprise glass, they might also be referred to as a first glass layer and a second glass layer.

In the context of the present document, the term “glass layer” may in particular refer to a layer (structure) that comprises glass material and is, at the same time, suitable to fulfill a barrier function, in particular regarding the migration of chemical species. In this context, the term “glass” may in particular refer to a non-crystalline and amorphous solid. In a preferred example, the glass comprises silicate, in particular silicon dioxide (SiO₂) and/or soda lime glass, and/or borosilicate glass and/or aluminosilicate glass and/or lithium silicate glass and/or alkaline free glass. In a further example, the glass comprises at least one silane and/or siloxane compound. In yet another example, the glass may comprise functional groups, e.g. hydrophilic and/or hydrophobic functional groups, in particular at the main surfaces. Since the glass layer is a (continuous or discontinuous) layer, it comprises two main surfaces opposite each other.

By having a glass layer it is possible to implement an electrically insulating material layer having a good mechanical stability, with excellent electrically insulating and barrier properties in respect to, in particular, chemical species.

If the electrically insulating material layer and/or the second electrically insulating material layer are made of or comprise polymeric material and/or epoxy, it is possible to have a softer structure, thus reducing the overall warpage, while still providing excellent electrically insulating properties.

According to an embodiment, the first electrically insulating material layer and/or the second electrically insulating material layer comprises a filler material, in particular a glass filler, in particular fibers, more in particular glass fibers.

A filler material might be a material showing different mechanical, electrical, physical and/or chemical properties with respect to the material of the first insulating material layer and/or the second insulating material layer. The filler material might in particular provide an improved mechanical stability to the first insulating material layer and/or the second insulating material layer.

The filler material comprises particles, in particular nanoparticles, wires, in particular nanowires, and/or fibers. The filler material might comprise at least one of the following materials: glass, carbon or organic compounds.

According to an embodiment, the first via and the second via are electrically and/or thermally and/or mechanically connected within the central layer.

By connecting the first via with the second via directly to each other in the central layer, an improved electrical signal transmission, thermal dissipation and/or mechanical stability of the inlay can be achieved.

According to an embodiment, the central layer is made of or comprises an anisotropic conductive film (ACF).

The anisotropic conductive film might be in particular a thermosetting resin, such as epoxy, the resin may consist of or is made of adhesive material comprising conductive means or particles for allowing an electrical and/or thermal connection between the first via and the second via.

The ACF might be provided in the form of a film or of a paste.

The use of the ACF simplifies the manufacturing process by making it more efficient and less cost intensive. Furthermore, if ACF is used, the thickness of the first electrically insulating material layer and/or of the second electrically insulating material layer might be increased.

According to an embodiment, the central layer comprises a matrix with embedded electrically conducting fillers.

In the present document, a matrix is a material structure in which thermally and/or electrically conducting means are placed in a grid at regular or irregular distances from one another.

By using a matrix, it is possible to have a central layer in which the first and the second via are connected to each other electrically and or/thermally without the need of designing the central layer specifically for a combination of a first electrically insulating material layer and a second insulating material layer.

According to an embodiment, the electrically conducting fillers might be electrically insulating in a plane perpendicular to the vertical (z) direction of the inlay and electrically conducting in a vertical (z) direction of the inlay. In such embodiment, the first via and the second via might be joined by applying heat and pressure, in order to create an electrically conducting connection in the vertical (z) direction of the inlay.

Another possibility might be that electrically conducting fillers having different sizes are provided in the matrix, such that electrically conducting fillers with bigger size are provided in a region of the first via and the second via. In such a way, when applying heat and/or pressure, the bigger electrically conducting fillers break to therefore connect the first via and the second via one with the other.

According to an embodiment, the embedded conducting fillers comprise at least one of conductive nanodots, conductive nanowires or tin cups or plastic particles plated with metal (Au or Ni or other metal).

Conductive nanodots might for example refer to small particles in the nanometer range of conductive material. Conductive nanowires might refer to a single filament or multifilament elongated material filaments made of conductive material. The conductive nanodots and/or the conductive nanowires might be made of or comprise a material being different from the one of the first via and/or of the second via. For example, it is possible that the first via and/or the second via is made of or comprises copper and that the conductive nanodots and/or the conductive nanowires are made of or comprise gold.

Tin cups might refer to an additional layer of tin deposited on a surface of the first via and/or of the second via inside of the central layer. By using tin cups, it is possible to have a solder type connection between the first via and the second via during the manufacturing process, whereby such solder like connection is achieved by means of a thermal step, which causes the tin layer to melt.

According to an embodiment, at least one of the first electrically insulating material layer and the second electrically insulating material layer comprises at least one cavity, wherein the inlay further comprises at least one component arranged in the cavity.

Therefore, it is possible to arrange a component, such as a conductive die, inside the cavity. The component might be connected electrically and/or thermally through the central layer to the first via and/or the second via.

It might also be the case that both the first electrically insulating material layer and the second electrically insulating material layer comprises at least one cavity, in which it is arranged a component, wherein the component arranged in the cavity of the first electrically insulating material layer and the component arranged in the cavity of the second electrically insulating material layer are connected to each other electrically and/or thermally through the central layer.

According to an embodiment, the inlay further comprises an adhesion layer, in particular a die attach film, arranged in the at least one cavity and wherein the adhesion layer is arranged between the central layer and the component.

In such a way, it is possible to increase the adhesion of the component to the central layer. In an embodiment, the adhesion layer is a conductive adhesion layer.

According to an embodiment, a filler material for filling the cavity in which the component is placed might be provided. In such case, it is possible to improve the stability, in particular the mechanical stability, of the component inside of the cavity.

According to an embodiment, the cavity extends inside the central layer and/or the adhesion layer is embedded in the first electrically insulating material layer and/or the second electrically insulating material layer and/or the central layer. When the cavity extends in the central layer it is possible to have a better electrical and/or thermal connection of the component to, for example, the first via and/or the second via. When the adhesion layer is embedded in the first electrically insulating material layer and/or the second electrically insulating material layer and/or the central layer, a more compact structure of the inlay might be obtained.

According to an embodiment, the first electrically insulating material layer is made of a first material and the second electrically insulating material layer is made of a second material and wherein the first material has a different composition with respect to the second material.

In such a way, it is possible to achieve different properties for the first electrically insulating material layer and the second electrically insulating material layer of the inlay, depending on the applications of the inlay.

According to an embodiment, the first electrically insulating material layer and/or the second electrically insulating material layer is preferably a glass layer and is made of or comprises at least one of the following chemical compositions: SiO₂, Na₂O, MgO, CaO, B₂O₃, Al₂O₃, PbO, K₂O, Fe₂O₃, Bao, ZnO, La₂O₃, CeO₂, GeO₂, TeO₂, TiO₂, Na₂CO₃ Sb₂O₃, Ta₂O₅.

Si₂O is the basic component for a glass layer, which might be compounded with other chemical compounds for improving the qualities of the glass. Na₂CO₃ lowers the glass transition temperature. CaO, MgO and Al₂O₃ might be added to improve chemical durability. B₂O₃ has the effect of reducing the thermal expansion, so that the first electrically insulating material layer and/or the second electrically insulating material layer might be made less subject to thermal stresses caused by thermal expansions, and thus less vulnerable to cracking from thermal shocks. The addition of PbO lowers the melting point of the first electrically insulating material layer and/or the second electrically insulating material layer and renders it less viscous. Also, PbO increases the absorption of x-ray radiation of the first electrically insulating material layer and/or the second electrically insulating material layer. PbO in addition with K₂O and Na₂O increases the elasticity of the first electrically insulating material layer and/or the second electrically insulating material layer, thus improving mechanical properties of the inlay. Al₂O₃ improves the thermal resistance of the first electrically insulating material layer and/or the second electrically insulating material layer and thus increases the overall durability of the inlay. BaO increases the refractive index of the first electrically insulating material layer and/or the second electrically insulating material layer. B₂O₃ improves the resistance of the first electrically insulating material layer and/or the second electrically insulating material layer against chemicals. K₂O, ZnO, Ta₂O₅ might be used to lower the melting point of the first electrically insulating material layer and/or the second electrically insulating material layer to facilitate the manufacturing process. GeO₂ might improve the qualities of the first electrically insulating material layer and/or the second electrically insulating material layer in respect to the light transmittivity, in particular if the inlay has waveguides. CeO₂ improves the absorption of ultraviolet radiation. TeO₂, TiO₂ improves the refractivity of the first electrically insulating material layer and/or the second electrically insulating material layer. Fe₂O₃ improves the heat absorption properties of the first electrically insulating material layer and/or the second electrically insulating material layer. Sb₂O₃ and La₂O₃ are common compounds found in inlays with electrically insulating material.

According to an embodiment, the first electrically insulating material layer has a first thickness and the second electrically insulating material layer has a second thickness the first thickness different from the second thickness. Therefore, it is possible to have an inlay with electrically insulating material layers having different thicknesses in accordance with the necessities of the inlay. For example, it is possible to have a thicker layer for hosting a component in a cavity and a thinner layer, in which only one or more vias are provided for connecting purposes.

According to an embodiment, the first electrically insulating material layer and/or the second electrically insulating material layer has a thickness being greater than 500 μm, preferably greater than 800 μm. Thus, it is possible to have an electrically insulating material layer with thicknesses being greater than those known in the art.

According to an embodiment, the first via comprises a first protruding section extending into the central layer in a vertical direction of the inlay and the second via comprises a second protruding section extending into the central layer in a vertical direction of the inlay, wherein the inlay comprises at least one of the following features: the first protruding section comprises a first connecting surface in a vertical of the inlay and the second protruding section comprises a second connecting surface in the vertical of the inlay, and the first connecting surface has a different size with respect to a size of the second connecting surface; the first protruding section extends into the central layer for a first extension depth and the second protruding section extends into the central layer for a second extension depth, and the first extension depth and the second extension depth are different.

Although not explicitly stated, the first extension depth and the second extension depth might be the same.

Therefore, it is possible to take care of possible misalignments between the first electrically insulating material layer and/or the second electrically insulating material layer by having a protruding section of the first via and/or of the second via with a connecting surface being larger than the connecting surface of the protruding section of the other via. Also, it is possible to have a via penetrating deeper in the central layer than the other, in order to improve the connection between the first via and the second via.

According to an embodiment, the first via and/or the second via have a cross-section with a varying surface along the vertical direction of the inlay. Thus, it is possible to have a variable section of the first via and/or the second via, in order to obtain the desired form of the first via and/or the second via.

According to an embodiment, the cross-section has a bigger surface at an outer surface of the first electrical insulating material layer and/or of the second electrical insulating material layer and a smaller surface at an inner surface of the first electrical insulating material layer and/or of the second electrical insulating material layer, so that the first via and/or the second via has a tapered shape in a plane containing the vertical direction of the inlay.

If both the first via and the second via are tapered from the outer surface of the first electrically insulating material layer and/or the second electrically insulating material layer towards the inner surface of the first electrically insulating material layer and/or the second electrically insulating material layer, then the vias have an hour-glass shape.

It is however also possible that the first via and/or the second via have a diminishing cross-section from the internal surface of the first electrically insulating material layer and/or the second electrically insulating material layer towards the outer surface of the first electrically insulating material layer and/or the second electrically insulating material layer.

According to an embodiment, the first electrically insulating material layer comprises at least one further first via, wherein the first via and the at least one further first via extend at least partially into the central layer, and the first via and the at least one further first via are arranged in a vertical direction facing the second via.

Therefore, it is possible that more vias in the first electrically insulating material layer contact the second via in the second electrically insulating material layer. In particular, the first via and the further first via have a first protruding section with a first connecting surface and a further first protruding section with a further first connecting surface, wherein the first connecting surface and the further first connecting surface are arranged along a vertical projection of a second contacting surface of the second via. Thus, a better connection between the first via and the further first via on the one side and the second via on the other side might be achieved.

According to an embodiment, the inlay comprises at least one electric contact, in particular a solder ball, arranged at an outer surface of the first electrically insulating material layer or the second electrically insulating material layer, wherein the electric contact contacts the first via or the second via.

Thus, it is possible to connect electric components to the inlay.

It might also be the case that more electric contacts are provided, on an outer surface of the first electrically insulating material layer and/or the second electrically insulating material layer, so that more electric components might be connected to the inlay and/or one electric component might be connected to more than one electric contact.

According to an embodiment, the first via and/or the second via extends into the central layer for less than 10 μm, preferably less than 5 μm.

According to an embodiment, the inlay comprises at least one metallization layer (seed layer) extending over at least one, preferably two of the first electrically insulating material layer, the central layer and the second electrically insulating material layer. Thus, it is possible to have a seed layer over at least one, preferably two, layers of the inlay for grooving vias.

According to an embodiment, the inlay comprises at least one of the following features:
the first via and the second via are not aligned along a vertical direction of the inlay;
the first via and/or the second via have a cross-section with respect to a vertical direction of the inlay, whose characteristic dimension is less than 200 μm, in particular less than 100 μm;
a plurality of first vias and a plurality of second vias are provided, wherein each via of the plurality of first vias is connected to a corresponding via of the plurality of the second vias.

In the present document, a characteristic dimension of the first via and/or of the second via might be the maximum dimension of the cross-section of the first via and/or of the second via in a plane perpendicular to the vertical direction of the inlay.

The first via and/or the second via might have also a cross-section with respect to a vertical direction of the inlay, whose characteristic dimension is less than 50 μm. Generally, the smaller the cross-section of the first via and/or of the second via, the better the mechanical properties of the first via and/or of the second via.

According to an embodiment, the inlay further comprises a stack with at least one electrically insulating layer structure and/or at least one electrically conducting layer structure, wherein the stack is arranged on an outer surface of the first electrically insulating material layer or the second electrically insulating material layer. Therefore, it is possible to integrate a stack of a component carrier directly on the inlay.

According to an embodiment of the method, providing the first electrically insulating material layer and/or providing the second electrically insulating material layer comprises the following step: forming, in particular drilling, preferably microdrilling, more preferably laser drilling the first via in the first electrically insulating material layer and/or the second via in the second electrically insulating material layer.

Therefore, common procedures might be used for forming the vias.

According to an embodiment of the method, the inlay is manufactured in a build-up process of a component carrier. Therefore, a bottom-up approach can be used in manufacturing the inlay as an integral part of the component carrier.

According to an embodiment of the method, providing the first electrically insulating material layer and/or providing the second electrically insulating material layer comprises the following step: forming the via with an electrically conducting material, the via having a protruding section protruding with respect to an inner surface of the electrically insulating material layer.

According to an embodiment of the method, arranging the central layer comprises the following step: arranging the first electrically insulating material layer and/or the second electrically insulating material layer on the central layer, such that the protruding section penetrates the central layer.

The apparatus features of the first aspect of the present disclosure related to the inlay are meant to be integrable in the embodiments related to the third aspect of the disclosure related to the method of manufacturing the inlay and the method features of the method of manufacturing the inlay are meant to be integrable in the embodiments related to the first aspect of the present disclosure related to the inlay.

In an embodiment, the component carrier is configured as one of the group consisting of a printed circuit board, a substrate (in particular an IC substrate), and an interposer.

In an embodiment, the component carrier is shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the component carrier stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layer structures or component carrier.

In particular, an electrically insulating solder resist may be applied to one or both opposing main surfaces of the layer stack or component carrier in terms of a surface treatment. For instance, it is possible to form such a solder resist on an entire main surface and to subsequently pattern the layer of solder resist to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of a surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples of appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1A shows an embodiment of the inlay according to the first aspect of the present disclosure.

FIG. 1B shows a detailed particular of the embodiment of the inlay according to FIG. 1A.

FIG. 2 shows another embodiment of the inlay according to the first aspect of the present disclosure.

FIG. 3 shows another embodiment of the inlay according to the first aspect of the present disclosure.

FIG. 4 shows another embodiment of the inlay according to the first aspect of the present disclosure.

FIG. 5 shows another embodiment of the inlay according to the first aspect of the present disclosure.

FIG. 6A shows another embodiment of the inlay according to the first aspect of the present disclosure.

FIG. 6B shows a detailed particular of the embodiment of the inlay according to FIG. 6A.

FIG. 7 shows another embodiment of the inlay according to the first aspect of the present disclosure.

FIG. 8 shows another embodiment of the inlay according to the first aspect of the present disclosure.

FIG. 9A, FIG. 9B, FIG. 9C, FIG. 9D, FIG. 9E, FIG. 9F, FIG. 9G, FIG. 9H, FIG. 9I, FIG. 9J, FIG. 9K, FIG. 9L, FIG. 9M, FIG. 9N, FIG. 90, and FIG. 9P show a method of manufacturing of an inlay according to the third aspect of the present disclosure.

It is herewith noted that reference numerals with the last two numbers being equal refer to equal or equivalent features, which fulfil the same function and for which the reference numeral is not always repeated.

### DETAILED DESCRIPTION OF ILLUSTRATED EMBODIMENTS

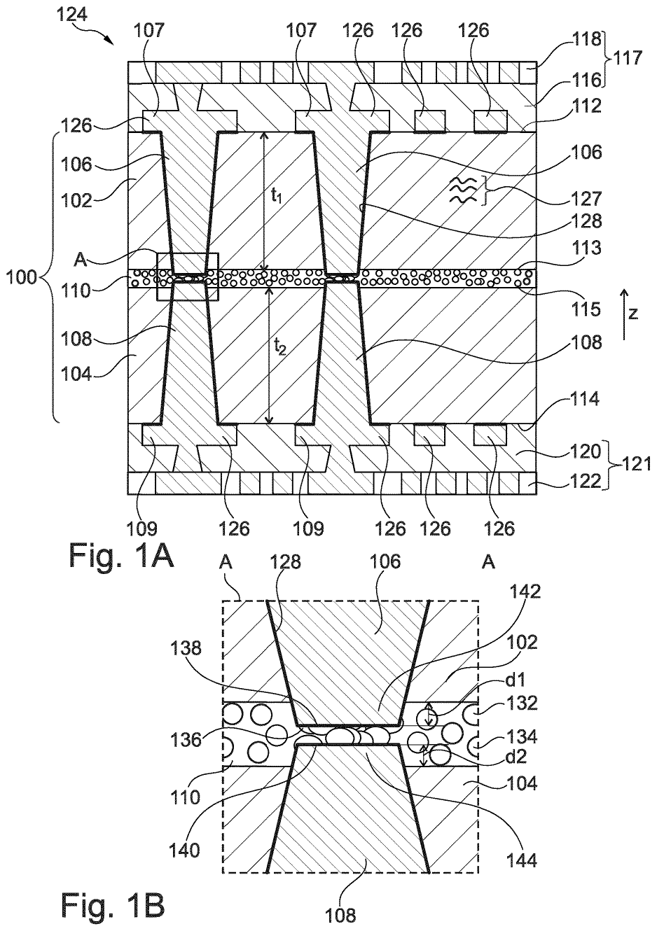

FIG. 1A shows an inlay 100 according to a first embodiment of the present disclosure.

The inlay 100 comprises a first electrically insulating material layer 102 with a first vias 106, a central layer 110 and a second electrically insulating material layer 104 with a second vias 108. All of the vias 106, 108 extend at least partially in the central layer 110.

The first electrically insulating material layer 102, the central layer 110 and the second electrically insulating material layer 104 are stacked together along a vertical direction z (also referred to as z-direction) of the inlay 100.

In the embodiment according to FIG. 1A, the first electrically insulating material layer 102 and the second electrically insulating material layer 104 have a thickness t1, t2 along the vertical direction z of the inlay which is at least 800 μm.

Also, in the embodiment according to FIG. 1A, the first vias 106 and the second vias 108 have both a tapered shape, so that they have a cross-section with a varying surface along the vertical direction z of the inlay 100, wherein the cross-section has a bigger surface at the outer surfaces 112, 114 and a smaller surface at inner surfaces 113, 115 of the first electrical insulating material layer 102 and of the second electrical insulating material layer 104. In the present embodiment, therefore, the first via 106 and the second via 108 form an hour-glass shaped connection through the inlay 100.

On an outer surface 112 of the first electrically insulating material layer 102 there is an electrically insulating layer structure 116, on which a further electrically conducting layer structure 118 is arranged, wherein the electrically insulating layer structure 116 and the electrically conducting layer structure 118 form a stack 117. Symmetrically, on an outer surface 114 of the second electrically insulating layer structure 104 there is an electrically insulating material layer structure 120 on which an electrically conducting layer structure 122 is arranged, wherein the electrically insulating layer structure 120 and the electrically conducting layer structure 122 form a stack 121. The first vias 106 are connected to the electrically conducting layer structure 118 by connecting protrusions 107 and electric contact elements, which are referred to as electric contacts 126. Similarly, the second vias 108 are connected to the electrically conducting layer structure 122 by protrusions 109 and electric contact elements, which are referred to as electric contacts 126. The electric contacts 126 are provided for connecting the inlay to external components, such as the stack formed by electrically insulating layer structures 116 and electrically conducting layer structures 116.

Thus, the inlay 100 is part of a component carrier 124. The inlay 100 can be built integrally with the component carrier 124 as part of a build-up manufacturing process of the component carrier 124 or the electrically insulating layer structures 116, 120 and the electrically conductive layer structures 118 and 122 might be formed separately in stacks, which are then stacked with the inlay 100 to from the component carrier 124.

In the present embodiment, the first electrically insulating material layer 102 and the second electrically insulating material layer 104 are made of glass and comprise, therefore, SiO₂ as a main component. The first electrically insulating material layer 102 and the second electrically insulating material layer 104 constitute therefore a first glass layer and a second glass layer, whose composition might comprise also, inter alia, at least one of SiO₂, Na₂O, MgO, CaO, B₂O₃, Al₂O₃, PbO, K₂O, Fe₂O₃, BaO, ZnO, La₂O₃, CeO₂, GeO₂, TeO₂, TiO₂, Na₂CO₃ Sb₂O₃, Ta₂O₅. The first electrically insulating material layer 102 and the second electrically insulating material layer 104 might however also be made of or comprise polymer or epoxy resins. The first electrically insulating material layer 102 and the second electrically insulating material layer 104 might also comprise a filler material 127 in particular glass filler and/or fibers, in particular glass microfibers, for reinforcing the first electrically insulating material layer 102 and the second electrically insulating material layer 104.

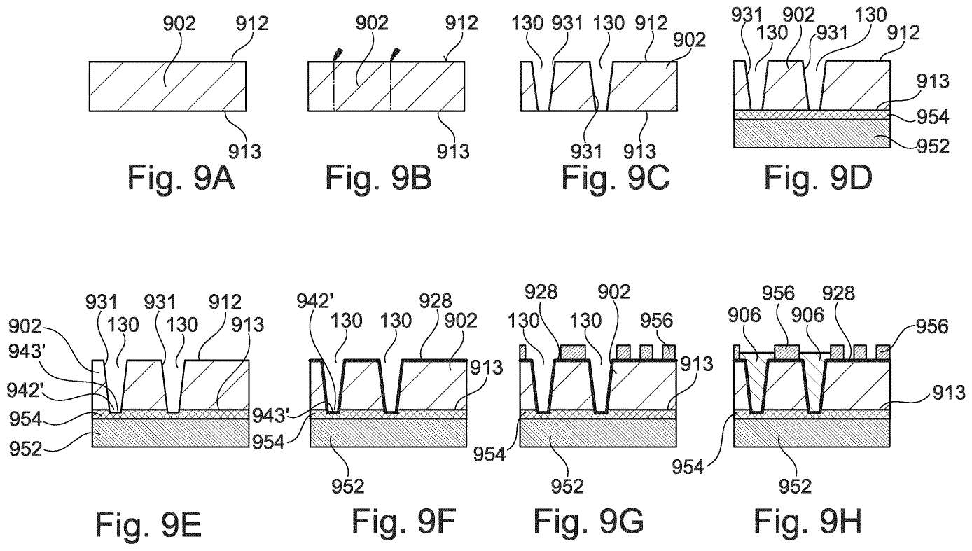

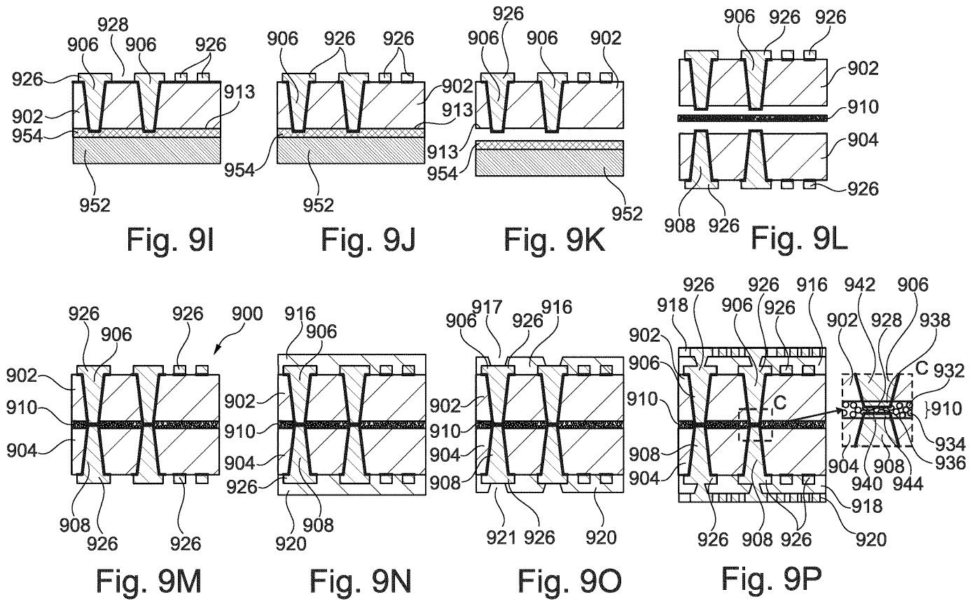

FIG. 1B is a detailed picture of detail A of FIG. 1A. In FIG. 1B there is depicted a magnification of a region in which first via 106 and the second via 108 extend at least partially in the central layer 110. As it can be seen in FIG. 1B, the first via 106 and the second via 108 are grown on seed (or metallization) layers 128, which is provided in through holes 130 (see FIG. 9C) of the first electrically insulating material layer 102 and of the second electrically insulating material layer 104 as well as in the central layer for allowing the material growth to realize the first via 106 and the second via 108. In the embodiment of FIG. 1A and FIG. 1B, the first via 106 and the second via 108 are realized with copper, though other materials might also be used.

The central layer 110, according to FIG. 1A and FIG. 1B, is an anisotropic conducting film (ACF) comprising conducting nanodots 132 and conducting nanowires 134, or plastic particles plated with metal (not shown), which form electrically conductive fillers. The central layer 110, according to FIG. 1A and FIG. 1B, might therefore be defined as a matrix with embedded electrically conductive fillers 132, 134. Tin cups 136 are also provided in the central layer 110 as fillers. The embedded electrically conductive fillers 132, 134, 136 facilitate an electrical connection of the first via 106 with the second via 108. In this particular embodiment, the first via 106 and the second via 108 are connected both electrically, thermally and also mechanically, as the tin cups 136 provided between a first connecting surface 138 of a first protruding section 142 of the first via 106 and a second connecting surface 140 of a second protruding section of the second via 108 create a solder type connection between the first via 106 and the second via 108. Although not shown in the figures, a metal-to metal bonding is also possible for connecting the first via 106 and the second via 108.

In FIG. 1B the first connecting surface 138 and the second connecting surface 140 have the same size. It might however be the case that different sizes for the first connecting surface 138 and the second connecting surface 140 are provided.

Also, in FIG. 1B, a first extension depth d₁ of the first protruding section 142 in the central layer 110 and a second depth d₂ of the second protruding section 144 in the central layer 110 are equal. It might however be the case that the first extension depth d₁ and the second extension depth d₂ are different from each other. The first extension depth d₁ and the second extension depth d₂ are preferably less than 10 μm, more preferably less than 5 μm.

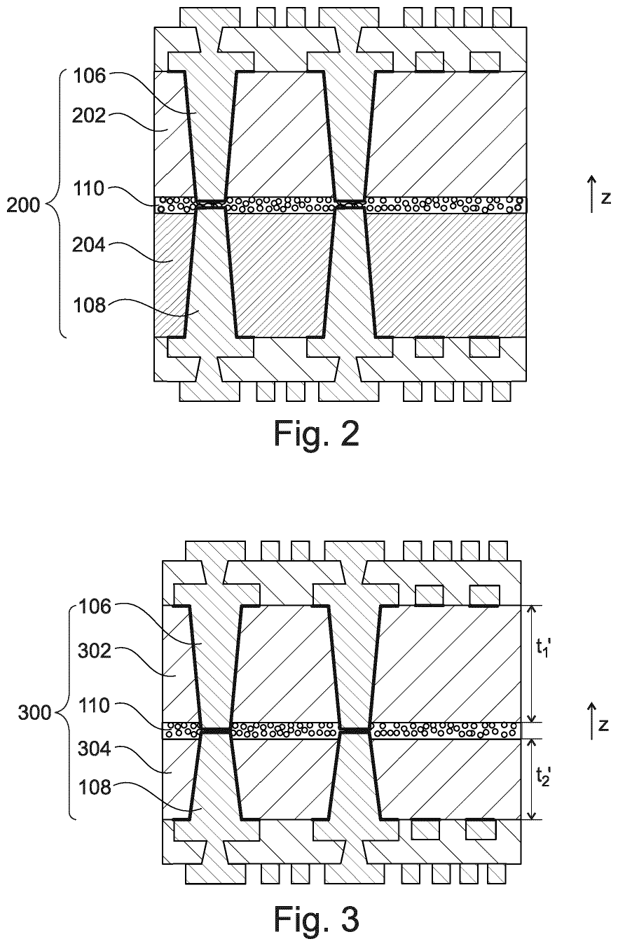

FIG. 2 represents a further embodiment of an inlay 200 according to the present disclosure. In FIG. 2, contrary to FIGS. 1A and 1B, a first electrically insulating material layer 202 is made of a first material and a second electrically insulating material layer 204 is made of a second material having a different composition with respect to the first material, so that different properties of the different materials forming the first electrically insulating material layer 202 and the second electrically insulating material layer 204 might be exploited.

FIG. 3 shows a further embodiment of an inlay 300 according to the present disclosure. Contrary to the embodiment of FIG. 1A and FIG. 1B, the inlay 300 according to FIG. 3 comprises a first electrically insulating material layer 302 having a first thickness t_{1′} and a second electrically insulating material layer 304 having a second thickness t_{2′}, wherein the first thickness t_{1′} and the second thickness t_{2′} are different from each other. In this example, the first thickness t_{1′} is bigger than the second thickness t_{2′}, however it might also be the case the first thickness t_{1′} is smaller than the second thickness t_{2′}.

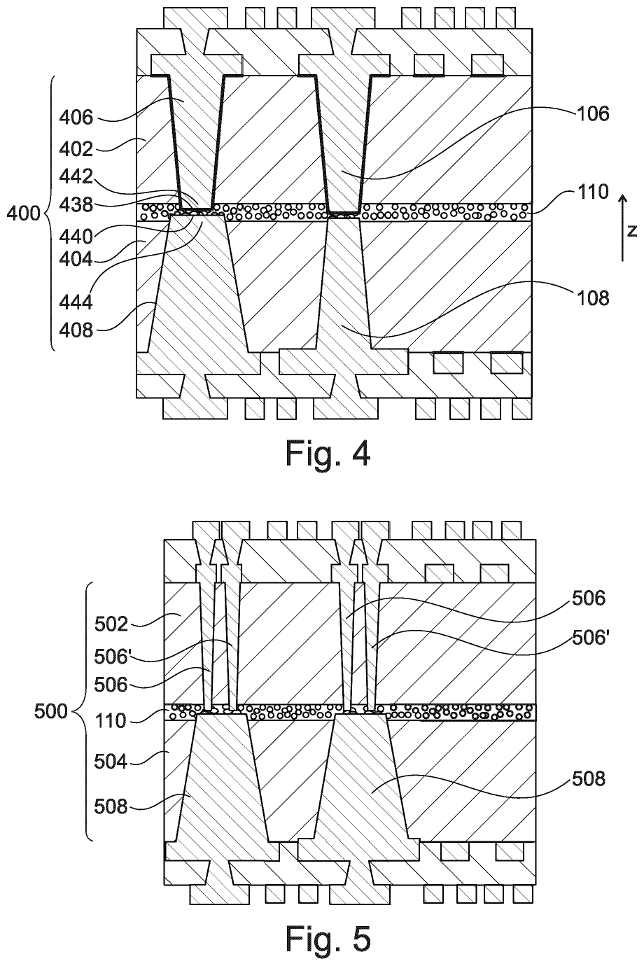

FIG. 4 shows a further embodiment of an inlay 400 according to the present disclosure. Contrary to the embodiment of FIG. 1A and FIG. 1B, the inlay 400 according to FIG. 4 comprises a first pair of first via 406 and second via 408 and a second pair of a first via 106 and a second via 108. The second pair of the first via 106 and the second via 108 is built in the same way as the first vias 106 and second vias 108 of FIG. 1A and FIG. 1B.

The first pair of the first via 406 and the second via 408 have, however, the peculiarity that a first protruding section 442 of the first via 406 extending into the central layer 110 in the vertical direction z of the inlay 100 has a first connecting surface 438 and a second protruding section 444 of the second via 408 extending into the central layer 110 in the vertical direction z of the inlay 100 has a second contacting surface 440, wherein the first contacting surface 438 and the second contacting surface 440 have cross-sections along the vertical direction z of the inlay 100 having different sizes, thus allowing for more tolerance in the manufacturing process.

FIG. 5 shows a further embodiment of an inlay 500 according to the present disclosure. Contrary to the embodiment of FIG. 1A and FIG. 1B, the inlay 500 according to FIG. 5 comprises first vias 506 and further first vias 506′ as well as second vias 508, wherein the first vias 506 and the further first vias 506′ extend at least partially into the central layer 110, and the first vias 506 and the at least one further first via 506′ are arranged in a vertical direction z facing the second vias 508. Therefore, in this example, a plurality of a first via 506 and a further first via 506′ are arranged to extend towards the second contacting surface 540 of the second via 508, so that the first via 506 and the further first via 506′ are connected to the single second via 508.

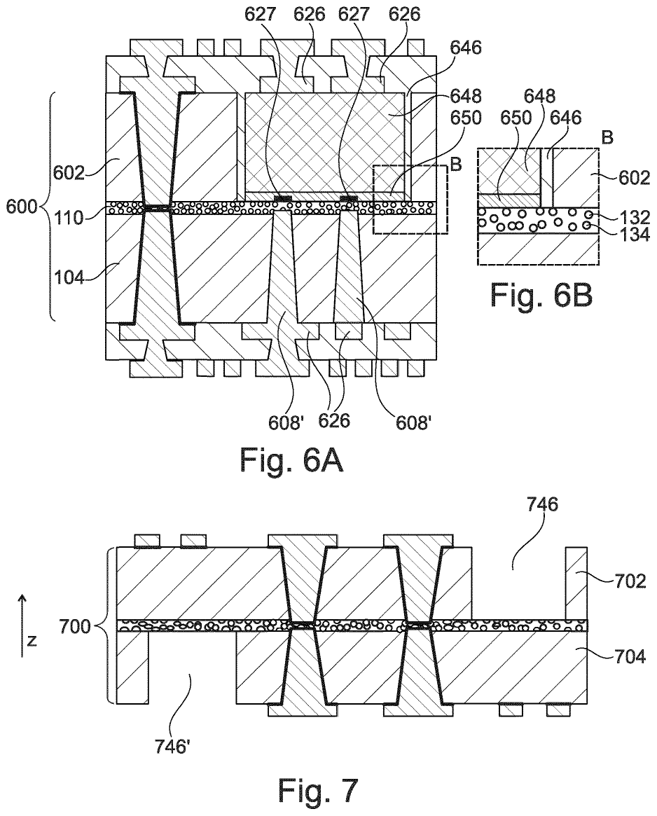

FIG. 6A and FIG. 6B shows a further embodiment of an inlay 600 according to the present disclosure. In the inlay 600 according to FIGS. 6A and 6B, there is a cavity 646 arranged in a first electrically insulating material layer 602, wherein a component 648 is arranged in the cavity 646. An adhesion layer 650 arranged in the cavity 646 between the component 648 and the central layer 110 is furthermore provided. In the example of FIG. 6A and FIG. 6B, the adhesion layer 650 is a conducive die attach film for improving the connection between the component 648 and the central layer 110 and for improving the mechanical stability of the component 648 in the cavity 646. Although not shown in FIG. 6A and FIG. 6B, there might be a filler in the cavity 646 for fixing the component 648 in a mechanically more stable way.

Further, as can be seen in FIG. 6A, a plurality of further second vias 608′ might be connected with the component 648 via bumps 627, so that the component 648 might be connected on both sides of the inlay 600. It might however also be the case that the component 648 is connected only on one side of the inlay 600, either by means of the further second vias 608′ or by means of the electric contacts 626.

FIG. 7 shows a further embodiment of an inlay 700 according to present disclosure, in which both a first electrically insulating material layer 702 and a second electrically insulating material layer 704 have a cavity 746, 746′ for arranging a component. In the example of FIG. 7, the cavities 746 and 746′ are not aligned in the z-direction, though the present disclosure also comprises the case in which they are aligned in the z-direction.

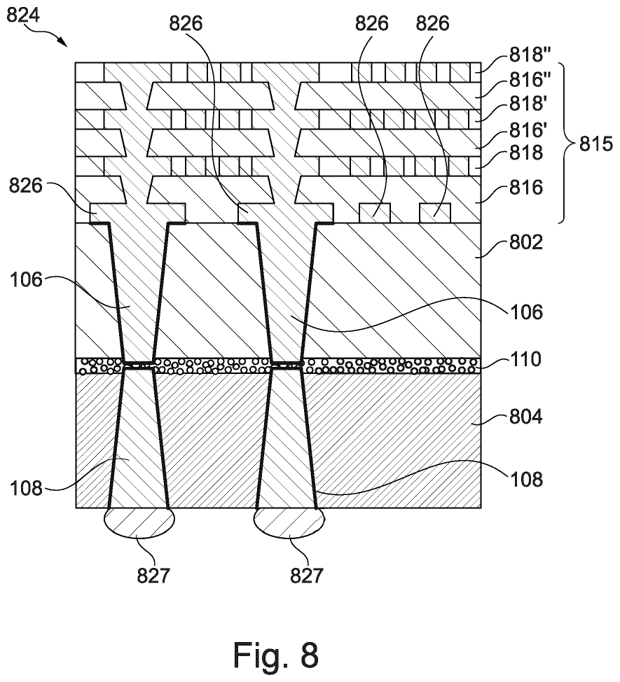

FIG. 8 shows an embodiment of a component carrier 824 comprising an inlay 800 according to any of the previous embodiments, which is connected, on the one side, with a stack 815 comprising electrically insulating material layers 816, 816′ and 816″ and electrically conducting material layers 818, 818′ and 818″ with electric contacts 826 for connecting the first vias 106 of the first electrically insulating material layer 802 to the stack of electrically insulating material layers structure 816, 816′ and 816″ and electrically conducting material layers structure 818, 818′ and 818″. On the other side electric contacts in form of solder balls 827, which are placed directly in contact with the second vias 108 of the second electrically insulating material layer 804. In this case, the component carrier 824 has therefore an asymmetric structure.

FIGS. 9A to 9P show a method of manufacturing of an inlay according to the third aspect of the present disclosure.

In a first step (FIG. 9A) a first electrically insulating material layer, such as a glass layer 902 with an outer surface 912 and an inner surface 913, is provided.

In a next step (FIG. 9B), through holes 130 (see FIG. 9C) are formed by drilling, in particular by microdrilling, more in particular by laser microdrilling, in the first electrically insulating material layer 902.

The through holes 130 of FIG. 9C are tapered, though the disclosure also comprises the case in which the through holes 130 are not tapered in such a way that they have a diminishing cross-section along a vertical axis z of the first electrically insulating material layer.

In a next step (FIG. 9D) the first electrically insulating material layer 902 is attached to a component carrier 952 via a die attach film 954.

In a next step (FIG. 9E) a plasma treatment is applied to the first holes 130, so that a protruding section 942′ with bottom 943′ for each through hole 130 can be formed in the die attach film 954.

In a next step (FIG. 9F) a metallization or seed layer 928 is deposited on the outer surface 912 of the first electrically insulating material layer 902 as well as on the walls 931 of the through vias and on the bottom 943′ of the recessed portion 942′.

In a next step (FIG. 9G) a dry film resist layer 956 is applied to the seed layer 928 on the outer surface 912 of the first electrically insulating material layer 902 according to a pre-determined masking configuration.

In a next step (FIG. 9H) first vias 906 are grown on the seed layer 928, so that they have a protruding portion extending into the die attach film 954.

In a next step (FIG. 9I) the dry film resist is stripped from the outer surface 912 of the first electrically insulating material layer 902 and electric contacts 926 are formed.

In a next step (FIG. 9) the seed layer 928 present on the outer surface 912 of the first electrically insulating material layer 902 is removed. For example, the seed layer 928 on the outer surface 912 of the first insulating material layer 902 is removed by flash etch technology.

In a next step (FIG. 9K) the first electrically insulating material layer 902 is removed from the component carrier 952 and the die attach film 954.

In a next step (FIG. 9L) a second electrically insulating material layer 904, built in an analogous manner as the first electrically insulating material layer 902, is provided along with a central layer 910, which might be an anisotropic conductive film with conductive nanodots 932, conductive nanowires 934 and tin cups 936 (see detailed magnification of FIG. 9P).

In a next step (FIG. 9M) the first electrically insulating material layer 902, the central layer 910 and the second electrically insulating material layer 904 are stacked together, preferably under the use of pressure and/or temperature, to form the inlay 900. During a stacking procedure under the influence of temperature, the tin cups 936 are temporarily melted and form a solder-type connection between the first vias 906 and the second vias 908, thus connecting them thermally, electrically and mechanically.

In a next step (FIG. 9N) electrically insulating material is placed on the outer surfaces 912, 914 of the first electrically insulating material layer 902 and of the second electrically insulating material layer 904 to form electrically insulating layer structures 916, 920. Correspondingly, electrically conducting layer material is placed on top of the electrically insulating layer structures 916, 920 to form electrically conducting layer structures 918, 922.

In a next step (FIG. 90) tapered through holes 917, 921 are formed in the electrically insulating layer structures 916, 920 for allowing the build-up of vias 919, 923, which are then contacted to electric contacts 926 (FIG. 9P).

Following the build-up of the component carrier 924 according to the method described in FIGS. 9A to 90, with electrically insulating structures 916, 920 and electrically conductive structures 918, 922 formed on both sides of the first electrically insulating material layer 902 and of the second electrically insulating material layer 904, it is therefore possible to provide the component carrier 924 with an electrical connection between a first side, at which the first electrically insulating material layer 902 is provided, and a second side, at which the second electrically insulating material layer 904 is provided. Such a connection enhances the performance of the component carrier 924. On top of that, the first electrically insulating material layer 902 and the second electrically insulating material layer 904 also improve the resistance of the inlay 900 and the, therefore, of the component carrier 924 against warpage.

It should be noted that the term “comprising” does not exclude other elements or steps, and the use of the article “a” does not exclude multiplicity. Elements described in conjunction with various embodiments can also be combined.

### REFERENCE SIGNS

100 inlay
102 first electrically insulating material layer
104 second electrically insulating material layer
106 first via
107 protrusion
108 second via
109 protrusion
110 central layer
112 outer surface of the first electrically insulating material layer
113 inner surface of the first electrically insulating material layer
114 outer surface of the second electrically insulating material layer
115 inner surface of the second electrically insulating material layer
116 electrically insulating layer structure
117 stack
118 electrically conducting layer structure
120 electrically insulating layer structure
121 stack
122 electrically conducting layer structure
124 component carrier
126 electric contact
127 filler material
128 seed or metallization layer
130 through holes
132 conductive nanodots
134 conductive nanowires
136 tin cups
138 first connecting surface
140 second connecting surface
142 first protruding section
144 second protruding section
200 inlay
202 first electrically insulating material layer
204 second electrically insulating material layer
300 inlay
302 first electrically insulating material layer
304 second electrically insulating material layer
400 inlay
402 first electrically insulating material layer
404 second electrically insulating material layer
406 first via
408 second via
438 first contacting surface
440 second contacting surface
442 first protruding section
444 second protruding section
500 inlay
502 first electrically insulating material layer
504 second electrically insulating material layer
506 first via
506′ further first via
508 second via
600 inlay
602 first electrically insulating material layer
608′ further second via
626 electric contact
627 bump
646 cavity
648 component
650 adhesion layer
700 inlay
702 first electrically insulating material layer
704 second electrically insulating material layer
746 cavity
746′ cavity
802 first electrically insulating material layer
804 second electrically insulating material layer
815 stack
816 electrically insulating material layer
816′ electrically insulating material layer
816″ electrically insulating material layer
818 electrically conductive material layer
818′ electrically conductive material layer
818″ electrically conductive material layer
824 component carrier
826 electric contact
827 solder balls
900 inlay
902 first electrically insulating material layer
904 second electrically insulating material layer
906 first via
908 second via
910 central layer
912 outer surface of the first electrically insulating material layer
913 inner surface of the first electrically insulating material layer
916 electrically insulating layer structure
918 electrically conductive layer structure
917 tapered through hole
920 electrically insulating layer structure
921 tapered through hole
926 electric contact
928 metallization or seed layer
931 wall
932 conductive nanodots
934 conductive nanowires
936 tin cups
938 first connecting surface
940 second connecting surface
942 first protruding section
942′ protruding section
943 bottom
944 second protruding section
952 component carrier
954 die attach film
956 dry film resist layer
d1 first extension depth
d2 second extension depth
t1 first thickness
t1′ first thickness
t2 second thickness
t2′ second thickness

1. An inlay, comprising:
a first electrically insulating material layer comprising at least one first via;
a second electrically insulating material layer comprising at least one second via; and
a central layer arranged between the first electrically insulating material layer and the second electrically insulating material layer,
wherein the first via and/or the second via extend at least partially into the central layer.

2. The inlay according to claim 1, wherein the first electrically insulating material layer and/or the second electrically insulating material layer is made of or comprises at least one of the following materials: inorganic material/compound, polymeric material or epoxy.

3. (canceled)

4. The inlay according to claim 1, wherein the first via and the second via are electrically and/or thermally and/or mechanically connected within the central layer.

5. The inlay according to claim 1, wherein the central layer is made of or comprises an anisotropic conductive film.

6. The inlay according to claim 1, wherein the central layer (110) comprises a matrix with embedded electrically conducting fillers (132, 134, 136).

7. The inlay according to claim 6, wherein the embedded conducting fillers comprise at least one of conductive nanodots, conductive nanowires or tin cups.

8. The inlay according to claim 1,
wherein at least one of the first electrically insulating material layer and the second electrically insulating material layer comprises at least one cavity, and
wherein the inlay further comprises at least one component arranged in the cavity.

9.-11. (canceled)

12. The inlay according to claim 1, wherein the first electrically insulating material layer has a first thickness and the second electrically insulating material layer has a second thickness and the first thickness is different from the second thickness.

13. The inlay according to claim 1, wherein the first electrically insulating material layer and/or the second electrically insulating material layer has a thickness greater than 500 μm.

14. The inlay according to claim 1,
wherein the first via comprises a first protruding section extending into the central layer in a vertical direction of the inlay and the second via comprises a second protruding section extending into the central layer in a vertical direction (z) of the inlay, and
wherein the inlay comprises at least one of the following features:
the first protruding section comprises a first connecting surface in a vertical direction of the inlay and the second protruding section comprises a second connecting surface in the vertical direction of the inlay, and the first connecting surface has a different size with respect to a size of the second connecting surface;
the first protruding section extends into the central layer for a first extension depth and the second protruding section extends into the central layer for a second extension depth, and the first extension depth and the second extension depth are different.

15. The inlay according to claim 1, wherein the first via and/or the second via have a cross-section with a varying surface along the vertical direction of the inlay.

16. The inlay according to claim 1, wherein the cross-section has a bigger surface at an outer surface of the first electrical insulating material layer and/or of the second electrical insulating material layer and a smaller surface at an inner surface of the first electrical insulating material layer and/or of the second electrical insulating material layer, such that the first via and/or the second via has a tapered shape in a plane containing the vertical direction of the inlay.

17. The inlay according to any of claims claim 1,
wherein the first electrically insulating material layer comprises at least one further first via,
wherein the first via and the at least one further first via extend at least partially into the central layer, and
the first via and the at least one further first via are arranged in a vertical direction facing the second via.

18. (canceled)

19. The inlay according to claim 1, wherein the first via and/or the second via extends into the central layer for less than 10 μm.

20. (canceled)

21. The inlay according to claim 1, wherein the inlay comprises at least one of the following features:
the first via and the second via are not aligned along a vertical direction (z) of the inlay;
the first via and/or the second via have a cross-section with respect to a vertical direction of the inlay whose characteristic dimension is less than 200 μm;
a plurality of first vias and a plurality of second vias are provided, wherein each via of the plurality of first vias is connected to a corresponding via of the plurality of the second vias.

22. (canceled)

23. A component carrier, comprising:
at least one electrically insulating layer structure and/or at least one electrically conducting layer structure, and
at least one inlay including a first electrically insulating material layer comprising at least one first via;
a second electrically insulating material layer comprising at least one second via; and
a central layer arranged between the first electrically insulating material layer and the second electrically insulating material layer,
wherein the first via and/or the second via extend at least partially into the central layer.

24. A method of manufacturing an inlay, comprising the following steps:
providing a first electrically insulating material layer comprising at least one first via;
providing a second electrically insulating material layer comprising at least one second via;
providing a central layer and arranging the central layer between the first electrically insulating material layer and the second electrically insulating material layer,
wherein the first via and/or the second via extends at least partially into the central layer.

25. The method according to claim 24, wherein providing the first electrically insulating material layer and/or providing the second electrically insulating material layer comprises the following step:
forming, by drilling the first via in the first electrically insulating material layer and/or the second via in the second electrically insulating material layer.

26. (canceled)

27. The method according to claim 24, wherein providing the first electrically insulating material layer and/or providing the second electrically insulating material layer comprises the following step:
forming the via with an electrically conducting material, wherein the via has a protruding section protruding with respect to an inner surface of the electrically insulating material layer.

28. The method according to claim 27, wherein arranging the central layer comprises the following step:
arranging the first electrically insulating material layer and/or the second electrically insulating material layer on the central layer, such that the protruding section penetrates the central layer.
